(19) United States
(12) Patent Application Publication
(10) Pub. No.: US 2025/0240930 A1
(43) Pub. Date: Jul. 24, 2025

(54) LIQUID COOLING SYSTEM AND SERVER

(71) Applicant: SHENZHEN ENVICOOL TECHNOLOGY CO., LTD., Shenzhen (CN)

(72) Inventors: Xiaoxin XU, Shenzhen (CN); Xiaolei AI, Shenzhen (CN); Xiaojin CHENG, Shenzhen (CN)

(73) Assignee: SHENZHEN ENVICOOL TECHNOLOGY CO., LTD., Shenzhen (CN)

(21) Appl. No.: 18/814,632

(22) Filed: Aug. 26, 2024

(30) Foreign Application Priority Data
Jan. 19, 2024 (CN) 202410084924.8

(51) Int. Cl. H05K 7/20; G01M 3/16; G01M 3/18

(52) U.S. Cl. CPC H05K 7/20772; G01M 3/165; G01M 3/182; G01M 3/186; H05K 7/20272

(57) ABSTRACT

The present application relates to the technical field of heat dissipation and specifically provides a liquid cooling system including a liquid cooling body, a liquid guide pipe, a first detection tape arranged on the liquid cooling body, and a second detection tape arranged on the liquid guide pipe. The first detection tape is configured to detect liquid leakage of the liquid cooling body, and the second detection tape is configured to detect liquid leakage of the liquid guide pipe. The second detection tape arranged on at least one liquid guide pipe is connected in series with the first detection tape arranged on at least one liquid cooling body communicated with the liquid guide pipe. The liquid guide pipe and the at least one liquid cooling body communicated with the liquid guide pipe can be used as a detection branch. The present application also provides a server.

### CROSS REFERENCE TO RELATED APPLICATIONS

The present application claims priority to Chinese Patent Application No. 202410084924.8, titled “LIQUID COOLING SYSTEM AND SERVER”, filed on Jan. 19, 2024 with the China National Intellectual Property Administration, which is incorporated herein by reference in its entirety.

### FIELD OF THE INVENTION

The present application relates to the technical field of heat dissipation, and in particular to a liquid cooling system and a server.

### BACKGROUND

With the increase of the power density of servers, there is a high requirement for heat dissipation. Compared with air cooling heat exchange, liquid cooling heat exchange can provide higher heat exchange efficiency to meet heat exchange requirements of servers. At present, the liquid cooling for servers mainly adopts cold plate liquid cooling, also known as a liquid cooling plate. The liquid cooling plate exchanges heat and cold with a high heat-generating element of a server, and then quickly transfer heat to the outside of the server by being connected to a heat exchange device through a liquid guide pipe.

During the operation of the server, a liquid cooling system may leak due to fatigue, vibration, or other reasons. If an electronic component of the server comes into contact with a leaking high-pressure liquid, a fault such as a short circuit may occur. Therefore, it is necessary to detect whether there is a leak in the liquid cooling system, and perform an operation such as shutdown in time when a leak is detected. A detection tape is typically provided below the liquid cooling system to detect leaks. When a leak is detected in the liquid cooling system, shutdown is performed and the entire liquid cooling system is disassembled for maintenance. However, it is difficult to determine the leakage location in the liquid cooling system in the above method, and the disassembly and maintenance of the whole liquid cooling system are costly and inefficient.

### SUMMARY

In view of the above, the object of the present application is to provide a liquid cooling system and a server which are structured to detect leakage of a liquid guide pipe and a liquid cooling body communicated with the liquid guide pipe, so that when the leakage is detected, the corresponding liquid guide pipe and the liquid cooling body communicated with the liquid guide pipe can be disassembled and repaired independently.

In order to achieve the above object, the present application provides the following technical solutions.

A liquid cooling system includes at least one liquid cooling body and at least one liquid guide pipe. The liquid guide pipe is communicated with the corresponding liquid cooling body. The liquid cooling body is provided with a first detection tape for detecting liquid leakage of the liquid cooling body, and the liquid guide pipe is provided with a second detection tape for detecting liquid leakage of the liquid guide pipe. The second detection tape arranged on at least one liquid guide pipe is connected in series with the first detection tape arranged on the at least one liquid cooling body communicated with the at least one liquid guide pipe.

Optionally, in the liquid cooling system, multiple liquid cooling bodies are connected in parallel to at least one liquid guide pipe, and the first detection tapes arranged on the multiple liquid cooling bodies connected in parallel are connected in series.

Optionally, in the liquid cooling system, the first detection tape is provided with a first joint at a position where the liquid guide pipe is connected to the liquid cooling body, and the second detection tape is provided with a second joint engaged with the first joint.

Optionally, in the liquid cooling system, each of the first detection tape and the second detection tape both include two detection wires arranged in a disconnected manner. The two detection wires of the first detection tape and the two detection wires of the second detection tape connected in series with the first detection tape are respectively connected in series into a group. The detection wires arranged in a disconnected manner in each group is configured to be connected to a collector to collect an electrical signal between the detection wires of the group.

Optionally, in the liquid cooling system, different groups of the detection wires arranged in a disconnected manner are respectively connected to different collectors, so as to independently collect electrical signals between the detection wires of the groups.

Optionally, in the liquid cooling system, at least two groups of the detection wires arranged in a disconnected manner are connected to a collector. A resistor is provided between the two detection wires arranged in a disconnected manner in each group, and the resistance of the resistor of each group is different from the resistance of the resistor of another group. The resistors are connected in series to form a resistance series circuit with its head and tail ends being connected to the collector so as to collect an electrical signal between the head and tail ends.

Optionally, in the liquid cooling system, each of the two detection wires in each group is provided with a detection piece extending towards the other of the two detection wires, and the detection pieces on the two detection wires of each group are spaced apart.

Optionally, in the liquid cooling system, the detection pieces on the two detection wires of each group are alternately distributed, and arranged at preset intervals.

Optionally, in the liquid cooling system, a first connection device is provided at an end of each liquid guide pipe, and is configured to be detachably connected to a second connection device arranged on a port that is provided on a water distributor or a water collector to be fitted with the liquid guide pipe, so as to communicate the liquid guide pipe with the port. The first connection device is configured to block the first liquid guide pipe when the first connection device is disconnected from the second connection device, and the second connection device is configured to block the port when the second connection device is disconnected from the first connection device.

The liquid cooling system according to the present application includes at least one liquid cooling body, at least one liquid guide pipe, a first detection tape provided on the liquid cooling body, and a second detection tape provided on the liquid guide pipe. The liquid guide pipe is communicated with the corresponding liquid cooling body or bodies. The first detection tape is configured to detect the liquid leakage of the liquid cooling body, and the second detection tape is configured to detect the liquid leakage of the liquid guide pipe. The second detection tape arranged on at least one liquid guide pipe is connected in series with the first detection tape arranged on the liquid cooling body or bodies communicated with the liquid guide pipe.

According to the liquid cooling system provided by the present application, the liquid cooling body is provided with the first detection tape for detecting liquid leakage, and the liquid guide pipe is provided with the second detection tape for detecting liquid leakage, wherein the second detection tape arranged on at least one liquid guide pipe is connected in series with the first detection tape arranged on at least one liquid cooling body communicated with the liquid guide pipe. Thus, the liquid guide pipe and the at least one liquid cooling body communicated with the liquid guide pipe can be used as a detection branch. When any one of the liquid guide pipe or the liquid cooling body or bodies on the detection branch leaks, it can be detected. The liquid guide pipe and the liquid cooling body or bodies on the detection branch can be disassembled together for maintenance. On one hand, with the above arrangement, the entire liquid cooling system does not need to be disassembled during maintenance, which improves maintenance efficiency and reduces maintenance costs. On the other hand, the liquid guide pipe and the liquid cooling body or bodies in communication with the liquid guide pipe do not need to be separately detected as detection branches, which simplifies the structure and facilitates the layout of piping.

To achieve the above object, a server is also provided in the present application, which includes any one of the liquid cooling systems described above. Since the liquid cooling system described above has the above technical effects, the server including the liquid cooling system should also have corresponding technical effects.

### BRIEF DESCRIPTION OF THE DRAWING

In order to more clearly illustrate the technical solutions in the embodiments of the present application or in the conventional technology, the following will briefly introduce drawings required in the description of the embodiments or the conventional technology. Apparently, the drawings in the following description are only some of the embodiments of the present application. For those skilled in the art, other drawings can also be obtained based on these drawings without creative efforts.

FIG. 1 is a schematic structural view of a liquid cooling system according to an embodiment of the present application;

FIG. 2 is a schematic view showing connection between a first detection tape and a second detection tape;

FIG. 3 is a schematic structural view of a first detection tape; and

FIG. 4 is a schematic view showing a detection principle of two groups of detection wires corresponding to one collector.

The reference signs in the figures are listed as follows:

liquid cooling body 1,
liquid guide pipe 2,
first detection tape 3,
second detection tape 4,
detection wire 51,
detection piece 52,
first resistor 53,
second resistor 54,
first connection device 6,
second connection device 7.

### DETAIL DESCRIPTION OF EMBODIMENTS

A liquid cooling system and a server are disclosed in the embodiments of the present application to realize leakage detection at different positions of the liquid cooling system, so that a part of the liquid cooling system can be disassembled and repaired separately when a leak is detected.

The technical solutions in the embodiments of the present application are clearly and completely described below in conjunction with the drawings. Apparently, the described embodiments are only part of the embodiments of the present application, not all of the embodiments of the present application. Any other embodiment obtained by those skilled in the art based on the embodiments in the present application without creative efforts shall fall within the protection scope of the present application.

The liquid cooling system according to the present application includes at least one liquid cooling body and at least one liquid guide pipe. The liquid guide pipe is communicated with a corresponding liquid cooling body or corresponding liquid cooling bodies. The liquid cooling body is generally a liquid cooling plate, but in some cases, may be of a block structure or any other structure. The liquid cooling body is used for heat exchange with a heating element of an electronic device such as a server. It can be understood that the heating element may include an element such as a processor that generates heat itself during the operation, or an element that is heated indirectly by absorbing heat generated by the self-heat generating element. The liquid cooling body has at least one heated surface which abuts against an electronic element to be cooled. That is, the heated surface of the liquid cooling body and a heat dissipation surface of the electronic element are in thermal contact.

The liquid guide pipe in the present application is configured to discharge a high-temperature liquid out of the liquid cooling body and introduce a low-temperature liquid into the liquid cooling body. It should be noted that the liquid in the liquid cooling body and the liquid guide pipe in the present application may be cooling water or refrigerant. The cooling water includes but is not limited to water or a mixture of water, e.g., anti-freezing cooling water added with ethylene glycol. The refrigerant includes but is not limited to a refrigerant added with fluorine. The liquid guide pipe includes a liquid inflow channel and a liquid outflow channel for liquid circulation, so as to allow the high-temperature liquid in the liquid cooling body to flow out and allow the low-temperature liquid to flow in the liquid cooling body. It can be understood that it may include a liquid inflow pipe and a liquid outflow pipe which are arranged separately, or may include a multi-cavity tube that is integrally arranged and has different cavities respectively for inflow and outflow of liquid. In the present application, the liquid cooling body and the liquid guide pipe are provided with a first detection tape and a second detection tape, respectively. With reasonable arrangement of the first detection tape and the second detection tape, the leakage position in the liquid cooling system can be detected, and the part of the liquid cooling system corresponding to the leakage position can be repaired conveniently. In the following embodiments, the arrangement of the first detection tape and the second detection tape and the connection of the liquid guide pipe are mainly described. Other structures of the liquid cooling system can refer to the conventional technology, and are not repeated here.

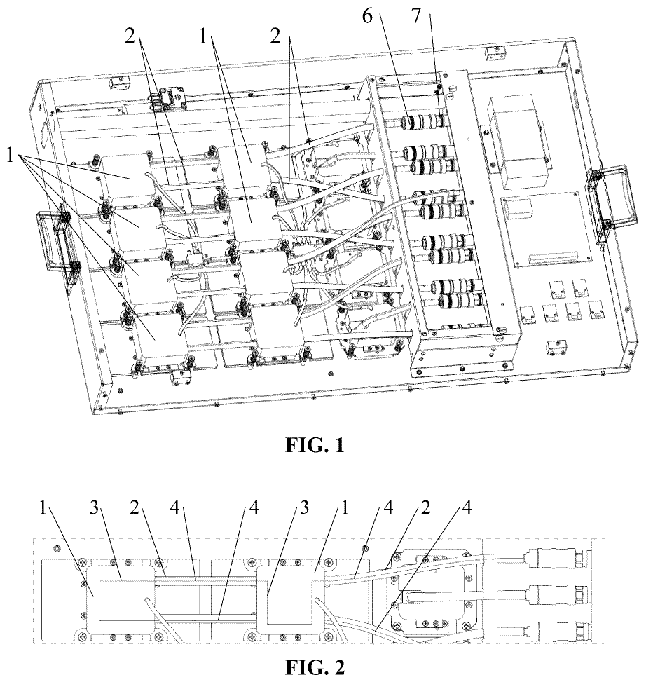

In an embodiment, referring to FIGS. 1 to 2, a liquid cooling system according to the present application includes at least one liquid cooling body 1, at least one liquid guide pipe 2, a first detection tape 3 provided on the liquid cooling body 1, and a second detection tape 4 provided on the liquid guide pipe 2. The liquid guide pipe 2 is communicated with a corresponding liquid cooling body 1 or corresponding liquid cooling bodies 1. The first detection tape 3 is configured to detect leakage of the liquid cooling body 1, and the second detection tape 4 is configured to detect leakage of the liquid guide pipe 2. The second detection tape 4 arranged on at least one liquid guide pipe 2 is connected in series with the first detection tape(s) 3 arranged on at least one liquid cooling body 1 communicated with the liquid guide pipe 2. That is, at least one liquid guide pipe 2 is communicated with at least one liquid cooling body 1, and together with the at least one liquid cooling body 1 communicated with the liquid guide pipe 2 serves as a detection branch. The first detection tape(s) 3 arranged on the detection branch is connected in series with the second detection tape 4 so that, when leakage occurs in the liquid guide pipe 2 or the liquid cooling body 1 on the detection branch, the leakage can be effectively detected. Therefore, the liquid guide pipe 2 and the liquid cooling body or bodies 1 on the detection branch can be disassembled together for maintenance, or all of the liquid cooling bodies 1 communicated with the liquid guide pipe 2 can be disassembled together as a disassembly unit for maintenance. Compared with each liquid guide pipe 2 and each liquid cooling body 1 separately serving as detection branches, the structure is simplified. The amount of data to be processed is reduced in a corresponding control process.

According to the liquid cooling system of the present application, the liquid cooling body 1 is provided with the first detection tape 3 for detecting liquid leakage, and the liquid guide pipe 2 is provided with the second detection tape 4 for detecting liquid leakage, wherein the second detection tape 4 arranged on at least one liquid guide pipe 2 is connected in series with the first detection tape(s) 3 arranged on the liquid cooling body or bodies 1 communicated with the liquid guide pipe 2. By the above arrangement, on one hand, the entire liquid cooling system does not need to be disassembled for maintenance, which improves maintenance efficiency and reduces maintenance costs. On the other hand, the liquid guide pipe 2 and the liquid cooling body or bodies 1 in communication with the liquid guide pipe 2 do not need to be individually detected as detection branches, which simplifies the structure and facilitates the layout of piping.

In some embodiments, the liquid guide pipe 2 includes a liquid inflow pipe and a liquid outflow pipe that are separately arranged. Each of the liquid inflow pipe and the liquid outflow pipe is provided with a second detection tape 4, and the first detection tape 3 on the liquid cooling body 1 connected between the liquid inflow pipe and the liquid outflow pipe is connected in series with the second detection tape 4 on the liquid inflow pipe and the second detection tape 4 on the liquid outflow pipe.

In some embodiments, the same liquid guide pipe 2 is communicated with multiple liquid cooling bodies 1. The liquid cooling body 1 is configured to exchange heat with a heating element. According to the heat dissipation requirements of the heating element, the multiple liquid cooling bodies 1 may be communicated with the same liquid guide pipe 2. The multiple liquid cooling bodies 1 may be connected in series or in parallel as needed. For a high heat-generating element, the multiple liquid cooling bodies 1 may be connected in parallel, that is, the liquid guide pipe 2 supplies cooling medium to each of the multiple liquid cooling bodies 1, so that each liquid cooling body 1 has a high heat exchange efficiency. For a low heat-generating element, the multiple liquid cooling bodies 1 may be connected in series, so that liquid flows sequentially through the multiple liquid cooling bodies 1 connected in series to take away the heat from the low heat-generating element, thereby meeting the heat dissipation requirements, simplifying the piping structure, and reducing energy consumption.

Further, in a case that multiple liquid cooling bodies 1 are communicated with the same liquid guide pipe 2, the first detection tape 3 on each of the multiple liquid cooling bodies 1 communicated with the same liquid guide pipe 2 is connected in series with the second detection tape 4 on the same liquid guide pipe 2. The liquid cooling body or bodies 1 and the liquid guide pipe 2 that are in communication are used as a detection branch, and can be disassembled as a unit for ease of maintenance since it is only required to disconnect and seal two ends of the detection branch. Therefore, the first detection tapes 3 on the multiple liquid cooling bodies 1 communicated with at least one liquid guide pipe 2 is connected in series with the second detection tape 4 on the liquid guide pipe 2, that is, the first detection tape 3 on each liquid cooling body 1 communicated with at least one liquid guide pipe 2 is connected in series with the second detection tape 4 on the liquid guide pipe 2. The structure is greatly simplified while facilitating independent local maintenance.

In some embodiments, at least one liquid guide pipe 2 is connected to multiple liquid cooling bodies 1 connected in parallel, and the first detection tapes 3 arranged on the multiple liquid cooling bodies 1 connected in parallel are connected in series. That is, the multiple liquid cooling bodies 1 communicated with the at least one liquid guide pipe 2 are connected in parallel. The liquid guide pipe 2 and the corresponding multiple liquid cooling bodies 1 connected in parallel are used as a detection branch, and the first detection tapes 3 on the detection branch is connected in series with the second detection tape 4. Each first detection tape 3 on the detection branch is connected in series with the second detection tape 4, facilitating the connection between adjacent two first detection tapes 3 and/or second detection tapes 4. An example of two liquid cooling bodies 1 connected in parallel to the liquid guiding tube 2 is explained below. For ease of explanation, the two liquid cooling bodies 1 are called a first liquid cooling body and a second liquid cooling body, respectively; the part of the liquid guide pipe 2 located before communication with the first liquid cooling body is called a first liquid guide portion; and the part of the liquid guide pipe 2 communicated between the first liquid cooling body and the second liquid cooling body is called a second liquid guide portion. The second detection tape 4 on the first liquid guide portion is firstly connected in series with the first detection tape 3 on the first liquid cooling body, which in turn is connected in series with the second detection tape 4 on the second liquid guide portion, which in turn is connected in series with the first detection tape 3 on the second liquid cooling body, thereby forming a detection branch. In a case that the first liquid guide portion includes a first liquid inflow pipe and a first liquid outflow pipe that are separately arranged and the second liquid guide portion includes a second liquid inflow pipe and a second liquid outflow pipe that are separately arranged, wherein each of these pipes is provided with a second detection tape 4. The second detection tape 4 on the first liquid inflow pipe is firstly connected in series with the first detection tape 3 on the first liquid cooling body, which in turn is connected in series with the second detection tape 4 on the second liquid inflow pipe, which in turn is connected in series with the first detection tape 3 on the second liquid cooling body, which in turn is connected in series with the second detection tape 4 on the second liquid outflow pipe, which in turn is connected in series with the second detection tape 4 on the first liquid outflow pipe. In other embodiments, the first detection tapes 3 arranged on the liquid cooling bodies 1 connected in parallel may also be connected in parallel and connected in series with the second detection tapes 4 on the liquid guide pipe 2, which can also form a detection branch for detection.

In some embodiments, the first detection tape 3 is provided with a first joint at a position where the liquid guide pipe 2 is connected with the liquid cooling body 1, and the second detection tape 4 is provided with a second joint engaged with the first joint. By provision of the first and second joints, the first detection tape 3 and the second detection tape 4 are laid on corresponding positions during assembly, and are connected in series through the first and second joints. This operation is convenient, and there is no need to adjust or destroy the structure of the first detection tape 3 and the second detection tape 4 during assembly.

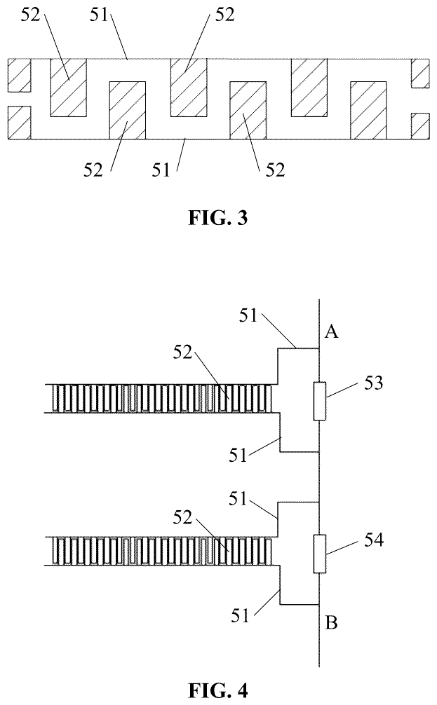

In some embodiments, referring to FIG. 3, each of the first detection tape 3 and the second detection tape 4 includes two detection wires 51 arranged in a disconnected manner. The two detection wires 51 of the first detection tape(s) 3 and the two detection wires 51 of the second detection tape(s) 4 connected in series with the first detection tape(s) 3 are respectively connected in series into a group. The detection wires 51 arranged in a disconnected manner in each group are configured to be connected to a collector to collect an electrical signal between the detection wires 51 of each group. The term “disconnected manner” here means that the two detection wires 51 are not connected. When the liquid cooling system leaks, for example, when the liquid cooling body 1 leaks, the two detection wires 51 of the first detection tape 3 are connected due to the presence of liquid, so that the collector can directly or indirectly collect an electrical signal such as a resistance between the two detection wires 51 or a current applied between the two detection wires. It can be determined whether the corresponding liquid cooling body 1 leaks based on the change of the electrical signal such as the resistance or the current. In the embodiment, two detection wires 51 of the first detection tape 3 and of the second detection tape 4 are respectively connected in series to realize the series connection of the first detection tape 3 and the second detection tape 4. The structure is simple and the assembly is convenient. It can be understood that the detection wires 51 arranged in a disconnected manner in each group are connected to the collector, and the detection wires 51 connected in series in multiple groups are connected to the collector. In a case that a first detection tape 3 is not connected in series with a second detection tape 4 in the liquid cooling system, that is, in the case that the first detection tape 3 or the second detection tape 4 is separately provided, two detection wires 51 of the first detection tape 3 separately arranged are regarded as a group, or two detection wires 51 of the second detection tape 4 separately arranged are regarded as a group, wherein the detection wires 51 in each group are connected to the collector. The collector collects the electrical signal between the detection wires 51 in each group to determine whether there is a leakage at the detection position corresponding to the detection wires 51 in the group.

In some embodiments, referring to FIG. 3, one of the two detection wires 51 in each group is provided with a detection piece 52 extending towards the other of the two detection wires 51, and the detection pieces 52 on the two detection wires 51 are spaced apart. It is noted that the detection pieces 52 on the two detection wires 51 being spaced apart means that the detection pieces 52 on the two detection wires 51 do not contact each other, and that the detection piece 52 on one of the two detection wires 51 in each group does not contact the other of the two detection wires 51. During the detection, a leakage can be detected when the leaking liquid contacts two detection pieces 52 at the same time, or contacts one of the two detection wires 51 and a detection piece 52 on the other of the two detection wires 51 at the same time, or contacts the two detection wires 51 at the same time. By provision of the detection piece 52, a distance between two detection wires 51 can be increased so as to increase a detection area, and the detection accuracy can be ensured by setting the distance between the detection pieces 52. The smaller the distance between the detection piece 52 and the detection wire 51, the higher the detection accuracy.

Further, the detection pieces 52 on two detection wires 51 of each group are alternately distributed at a preset interval. In an embodiment, the detection pieces 52 on each detection wire 51 are distributed in a comb shape, and the width of the detection piece 52 on each detection wire 51 may be greater than, less than, or equal to half of the distance between the two detection wires 51. It should be noted that the detection piece 52 shown in FIG. 3 has a rectangular cross-section, or may have a triangle cross-section, a trapezoid cross-section, an L-shaped cross-section, a T-shaped cross-section, etc., so long as the detection piece 52 is of a structure that protrudes from one of the two detection wires 51 toward the other of the two detection wires 51.

In some embodiments, different groups of the detection wires 51 arranged in a disconnected manner are respectively connected to different collectors, so as to separately collect electrical signals between the detection wires 51 in each group. By connecting each group of the detection wires 51 arranged in a disconnected manner to the corresponding collector, it can be directly determined that a leak occurs at the position corresponding to the group of detection wires 51 based on the change of the electrical signal collected by the collector. The determination is convenient and the response is quick.

In some embodiments, at least two groups of the detection wires arranged in a disconnected manner are connected to a collector. A resistor is provided between the two detection wires 51 arranged in a disconnected manner in each group. The resistance of the resistor of one of the groups is different from the resistance of the resistor of another group. The resistors are connected in series to form a resistance series circuit with the head and tail ends being connected to the collector to collect an electrical signal between the head and tail ends. It can be understood that the electrical signal between the head and tail ends of the resistance series circuit may be a detected resistance value between the head and tail ends, a detected current value applied between the head and tail ends, or the like. In the above embodiments, the collector corresponding to the detection wires 51 of each group that are arranged in a disconnected manner detects the electrical signal such as a resistance between the detection wires 51 of each group or a current applied between two detection wires of each group. The electrical signal such as the resistance or the current changes when the two detection wires 51 arranged in a disconnected manner in each group are connected due to liquid leakage, so as to determine whether the corresponding detection branch has a leakage. These embodiments are different from the above embodiments in that there is no need to provide the collectors separately for the respective groups of the detection wires 51 that are arranged in a disconnected manner, and the groups of the detection wires 51 arranged in a disconnected manner can share one collector. Therefore, it is only necessary to detect the electrical signal at the head and tail ends of the resistance series circuit, which further simplifies the structure, reduces the number of collectors, and reduces costs.

For ease of explanation, referring to FIG. 4, an example of two groups of detection wires 51 arranged in a disconnected manner sharing the same collector is given. The two groups of the detection wires 51 arranged in a disconnected manner are respectively called a first group and a second group. A first resistor 53 is connected between two detection wires 51 of the first group, and a second resistor 54 is connected between two detection wires 51 of the second group and has a resistance value different from that of the first resistor 53. One end of the first resistor 53 is connected in series with one end of the second resistor 54. The collector collects the resistance between the other end A of the first resistor 53 and the other end B of the second resistor 54. When the resistance value collected by the collector is within a first preset range, it indicates that there is a leakage at a detection position corresponding to the two detection wires 51 of the first group. When the resistance value collected by the collector is within a second preset range, it indicates that there is a leakage at a detection position corresponding to the two detection wires 51 of the second group. When the resistance value collected by the collector is within a third preset range, it indicates that there are leakages at detection positions corresponding to the two detection wires 51 in the first group and the two detection wires 51 in the second groups. The first preset range is a range from the resistance value of the second resistor 54 minus a preset value to the resistance value of the second resistor 54 plus the preset value; the second preset range is a range from the resistance value of the first resistor 53 minus the preset value to the resistance value of the first resistor 53 plus the preset value; the third preset range is a resistance range determined based on the resistance of the liquid; and the preset value may also be determined based on the resistance of the liquid. As an example, the resistance values of both the first resistor 53 and the second resistor 54 are much greater than the resistance value of the liquid, the preset value and the third preset range may be approximated as zero. When the resistance value of the second resistance 54 is collected by the collector, it indicates that there is a leakage at the detection position corresponding to the two detection wires 51 of the first group. When the resistance value of the first resistor 53 is collected by the collector, it indicates that there is a leakage at the detection position corresponding to the two detection wires 51 of the second group. When the resistance value collected by the collector is zero, it indicates that there are leakages at the detection positions corresponding to the two detection wires 51 of the first group and the two detection wires 51 of the second group. The determination principle in a case that three or more groups of detecting wires 51 arranged in a disconnected manner share one collector is similar to the above, and the leakage position can be determined by the change of the resistance value, which is not repeated.

Further, the resistance value of each resistor may be much greater than the resistance value of the liquid, so as to reduce the influence of the resistance of the liquid on the detected resistance. For example, the resistance value of each resistor may be increased or an additive may be added to reduce the resistance of the liquid, so that the resistance value of each resistor is much greater than the resistance value of the liquid. Specifically, the resistance value of each resistor may be set in a binary manner.

In some embodiments, one end of the liquid guide pipe 2 is provided with a first connection device 6. The first connection device 6 is configured to be detachably connected to a second connection device 7 arranged on a port that is provided on a water collector or a water distributor to be matched with the liquid guide pipe 2, so as to communicate the liquid guide pipe 2 with the corresponding port. The first connection device 6 can block the corresponding first liquid guide pipe 2 when disconnected from the second connection device 7, and the second connection device 7 can block the corresponding port when disconnected from the first connection device 6. That is, in normal operation, the first connection device 6 is connected with the second connection device 7, and the liquid guide pipe 2 is in communication with the corresponding port. When a leak occurs and maintenance is required, the first connection device 6 is separated from the second connection device 7, so that the liquid guide pipe 2 is separated from the corresponding port. In the separated state, the first connection device 6 blocks the liquid guide pipe 2, and the second connection device 7 blocks the corresponding port, thereby preventing liquid leakage. Through the above arrangement, each liquid guide pipe 2 and the liquid cooling body or bodies 1 communicated with the liquid guide pipe 2 can be taken as a disassembly unit. When any of the liquid guide pipe 2 or the liquid cooling body or bodies 1 of the disassembly unit leaks, the disassembly unit can be independently disassembled from the liquid cooling system for maintenance. There is no need to disassemble the entire liquid cooling system, thereby reducing maintenance costs and improving maintenance efficiency.

Specifically, the first detection device on each liquid cooling body 1 communicated with the same first connection device 6 is connected in series with the second detection device on the liquid guide pipe 2 communicated with the first connection device 6, so that the leakage of the liquid guide pipe 2 or each liquid cooling plate communicated with the first connection device 6 can be effectively detected. The liquid guide pipe 2 and the liquid cooling body or bodies 1 of the detection branch can be disassembled together for maintenance. The leakage detection of the liquid cooling body or bodies 1 or the liquid guide pipe 2 of the disassembly unit can be realized by collecting the electrical signal of the first detection tape 3 and the second detection tape 4 connected in series by one collector. The structure is simple.

In some embodiments, each of the first connection device 6 and the second connection device 7 includes a connection seat and a valve core. A flow channel is provided in the connection seat and a toggle head is provided on the connection seat. The valve core is slidably arranged in the connection seat, and is provided with a through hole and a groove. The toggle head on the connection seat of the first connection device 6 is configured to be inserted into the groove of the valve core of the second connection device 7, and the toggle head on the connection seat of the second connection device 7 is configured to be inserted into the groove of the valve core of the first connection device 6. The first connection device 6 and the second connection device 7 slide relative to each other, so that the two through holes can be synchronously aligned with the corresponding flow channels to open the first connection device 6 and the second connection device 7 or staggered with each other to block the first connection device 6 and the second connection device 7. When the two toggle heads drive the two valve cores to slide to a blocking position, the two toggle heads are engaged with the corresponding connection seats. Specifically, the two toggle heads drive the two valve cores to slide, so that the through hole of the valve core of the first connection device 6 and the flow channel of the connection seat of the first connection device 6 are aligned with each other to open the first connection device 6, and the through hole of the valve core of the second connection device 7 and the flow channel of the connection seat of the second connection device 7 are aligned with each other to open the second connection device 7. The flow channel of the first connection device 6 and the flow channel of the second connection device 7 are aligned with each other, and the first connection device 6 is communicated with the second connection device 7. The toggle head on the first connection device 6 is engaged with the connection seat of the second connection device 7, and the toggle head on the second connection device 7 is engaged with the connection seat of the first connection device 6, so as to realize the connection between the first connection device 6 and the second connection device 7. When the first connection device 6 and the second connection device 7 slide in opposite directions, the two toggle heads drive the two valve cores to slide, so that the through hole of the valve core of the first connection device 6 and the flow channel of the connection seat of the first connection device 6 are staggered with each other to close the first connection device 6, and the through hole of the valve core of the second connection device 7 and the flow channel of the connection seat of the second connection device 7 are staggered with each other to close the second connection device 7. The toggle head on the first connection device 6 can be pulled out from the second connection device 7, and the toggle head on the second connection device 7 can be pulled out from the first connection device 6, thereby realizing disassembly and separation.

In other embodiments, the first connection device 6 and the second connection device 7 may also be of a conventional quick-release structure. Alternatively, each of the first connection device 6 and the second connection device 7 may include a cut-off valve, and the two cut-off valves are detachably connected.

Based on the liquid cooling systems described above, a server is also provided according to the present application, which includes any one liquid cooling system described above. Since the server includes the liquid cooling system described above, the beneficial effects described the above embodiments are applied to the server.

The embodiments in the specification are described in a progressive manner, and each embodiment focuses on the difference from other embodiments. Same and similar parts in each embodiment may be referred to each other.

The above description of the embodiments is provided to enable those skilled in the art to implement or use the present application. Various modifications to the embodiments are apparent to those skilled in the art. General principles defined herein may be implemented in other embodiments without departing from spirits or scopes of the present application. Therefore, the present application is not limited to the embodiments shown herein, but is to be accorded the widest scope consistent with the principles and novel features disclosed herein.

1. A liquid cooling system comprising one or more liquid cooling body and one or more liquid guide pipe, wherein
each liquid guide pipe is communicated with at least one liquid cooling body,
the liquid cooling body is provided with a first detection tape for detecting liquid leakage of the liquid cooling body,
the liquid guide pipe is provided with a second detection tape for detecting liquid leakage of the liquid guide pipe, and
the second detection tape arranged on at least one liquid guide pipe is connected in series with the first detection tape arranged on the at least one liquid cooling body communicated with the at least one liquid guide pipe.

2. The liquid cooling system according to claim 1, wherein a plurality of the liquid cooling bodies are connected in parallel to at least one liquid guide pipe, and the first detection tapes arranged on the plurality of the liquid cooling bodies connected in parallel are connected in series.

3. The liquid cooling system according to claim 2, wherein the first detection tape is provided with a first joint at a position where the liquid guide pipe is connected with the liquid cooling body, and the second detection tape is provided with a second joint engaged with the first joint.

4. The liquid cooling system according to claim 1, wherein each of the first detection tape and the second detection tape includes two detection wires arranged in a disconnected manner,
the two detection wires of the first detection tape and the two detection wires of the second detection tape connected in series with the first detection tape are respectively connected in series into a group, and
the detection wires arranged in a disconnected manner in each group is configured to be connected to a collector to collect an electrical signal between the detection wires of the group.

5. The liquid cooling system according to claim 4, wherein different groups of the detection wires arranged in a disconnected manner are respectively configured to be connected to different collectors, so as to independently collect electrical signals between the detection wires of the groups.

6. The liquid cooling system according to claim 4, wherein at least two groups of the detection wires arranged in a disconnected manner are connected to a collector,
a resistor is provided between the two detection wires arranged in a disconnected manner in each group,
the resistance of the resistor of each group is different from the resistance of the resistor of another group, and
the resistors are connected in series to form a resistance series circuit with its head and tail ends being connected to the collector so as to collect an electrical signal between the head and tail ends.

7. The liquid cooling system according to claim 4, wherein each of the two detection wires in each group is provided with a detection piece extending towards the other of the two detection wires, and the detection pieces on the two detection wires of each group are spaced apart.

8. The liquid cooling system according to claim 7, wherein the detection pieces on the two detection wires of each group are alternately distributed at preset intervals.

9. The liquid cooling system according to claim 1, wherein a first connection device is provided at an end of each liquid guide pipe, and is configured to be detachably connected to a second connection device arranged on a port that is provided on a water distributor or a water collector to be fitted with the liquid guide pipe, so as to communicate the liquid guide pipe with the port,
the first connection device is configured to block the first liquid guide pipe when the first connection device is disconnected from the second connection device, and the second connection device is configured to block the port when the second connection device is disconnected from the first connection device.

10. The liquid cooling system according to claim 2, wherein each of the first detection tape and the second detection tape includes two detection wires arranged in a disconnected manner,
the two detection wires of the first detection tape and the two detection wires of the second detection tape connected in series with the first detection tape are respectively connected in series into a group, and
the detection wires arranged in a disconnected manner in each group is configured to be connected to a collector to collect an electrical signal between the detection wires of the group.

11. The liquid cooling system according to claim 3, wherein each of the first detection tape and the second detection tape includes two detection wires arranged in a disconnected manner,
the two detection wires of the first detection tape and the two detection wires of the second detection tape connected in series with the first detection tape are respectively connected in series into a group, and
the detection wires arranged in a disconnected manner in each group is configured to be connected to a collector to collect an electrical signal between the detection wires of the group.

12. The liquid cooling system according to claim 10, wherein different groups of the detection wires arranged in a disconnected manner are respectively configured to be connected to different collectors, so as to independently collect electrical signals between the detection wires of the groups.

13. The liquid cooling system according to claim 10, wherein at least two groups of the detection wires arranged in a disconnected manner are connected to a collector,
a resistor is provided between the two detection wires arranged in a disconnected manner in each group,
the resistance of the resistor of each group is different from the resistance of the resistor of another group, and
the resistors are connected in series to form a resistance series circuit with its head and tail ends being connected to the collector so as to collect an electrical signal between the head and tail ends.

14. The liquid cooling system according to claim 10, wherein each of the two detection wires in each group is provided with a detection piece extending towards the other of the two detection wires, and the detection pieces on the two detection wires of each group are spaced apart.

15. The liquid cooling system according to claim 11, wherein different groups of the detection wires arranged in a disconnected manner are respectively configured to be connected to different collectors, so as to independently collect electrical signals between the detection wires of the groups.

16. The liquid cooling system according to claim 11, wherein at least two groups of the detection wires arranged in a disconnected manner are connected to a collector,
a resistor is provided between the two detection wires arranged in a disconnected manner in each group,
the resistance of the resistor of each group is different from the resistance of the resistor of another group, and
the resistors are connected in series to form a resistance series circuit with its head and tail ends being connected to the collector so as to collect an electrical signal between the head and tail ends.

17. The liquid cooling system according to claim 11, wherein each of the two detection wires in each group is provided with a detection piece extending towards the other of the two detection wires, and the detection pieces on the two detection wires of each group are spaced apart.

18. The liquid cooling system according to claim 2, wherein a first connection device is provided at an end of each liquid guide pipe, and is configured to be detachably connected to a second connection device arranged on a port that is provided on a water distributor or a water collector to be fitted with the liquid guide pipe, so as to communicate the liquid guide pipe with the port,
the first connection device is configured to block the first liquid guide pipe when the first connection device is disconnected from the second connection device, and the second connection device is configured to block the port when the second connection device is disconnected from the first connection device.

19. The liquid cooling system according to claim 3, wherein a first connection device is provided at an end of each liquid guide pipe, and is configured to be detachably connected to a second connection device arranged on a port that is provided on a water distributor or a water collector to be fitted with the liquid guide pipe, so as to communicate the liquid guide pipe with the port,
the first connection device is configured to block the first liquid guide pipe when the first connection device is disconnected from the second connection device, and the second connection device is configured to block the port when the second connection device is disconnected from the first connection device.

20. A server, comprising a liquid cooling system, wherein the liquid cooling system comprises one or more liquid cooling body and one or more liquid guide pipe,
each liquid guide pipe is communicated with at least one liquid cooling body,
the liquid cooling body is provided with a first detection tape for detecting liquid leakage of the liquid cooling body,
the liquid guide pipe is provided with a second detection tape for detecting liquid leakage of the liquid guide pipe, and
the second detection tape arranged on at least one liquid guide pipe is connected in series with the first detection tape arranged on the at least one liquid cooling body communicated with the at least one liquid guide pipe.
